(19) United States
(12) Patent Application Publication
(10) Pub. No.: US 2022/0250973 A1
(43) Pub. Date: Aug. 11, 2022

(54) FLEXIBLE DISPLAYING SUBSTRATE AND FABRICATING METHOD THEREOF, AND DISPLAYING DEVICE

(71) Applicants: Mianyang BOE Optoelectronics Technology Co., Ltd., Mianyang (CN); BOE TECHNOLOGY GROUP CO., LTD., Beijing (CN)

(72) Inventors: Liting Zhang, Beijing (CN); Gaoqiang Wang, Beijing (CN); Lin Zhang, Beijing (CN); Changlin Hou, Beijing (CN); Quanjun Wang, Beijing (CN); Wen Sun, Beijing (CN)

(73) Assignees: Mianyang BOE Optoelectronics Technology Co., Ltd., Mianyang (CN); BOE TECHNOLOGY GROUP CO., LTD., Beijing (CN)

(21) Appl. No.: 17/482,997

(22) Filed: Sep. 23, 2021

(30) Foreign Application Priority Data
Feb. 7, 2021 (CN) 202110180157.7

(51) Int. Cl. C03C 17/42; C03C 17/34

(52) U.S. Cl. CPC C03C 17/42; C03C 17/3435; C03C 2217/281; C03C 2218/152; C03C 2217/213; C03C 2218/114

(57) ABSTRACT

A flexible displaying substrate includes: a first flexible film layer; a first barrier layer provided on a first surface of the first flexible film layer; a second barrier layer provided on one side of the first barrier layer further away from the first flexible film layer; and a second flexible film layer is provided between the first barrier layer and the second barrier layer; wherein at least one of a surface of the first barrier layer further away from the first flexible film layer and a surface of the second barrier layer closer to the first flexible film layer is provided with a slot, and a first orthographic projection of the second flexible film layer on the first flexible film layer and a second orthographic projection of the slot on the first flexible film layer at least partially overlap.

The application claims priority to Chinese Patent Application No. 202110180157.7, titled “FLEXIBLE DISPLAYING SUBSTRATE AND FABRICATING METHOD THEREOF, AND DISPLAYING DEVICE” and filed to the State Patent Intellectual Property Office on Feb. 7, 2021, the contents of which are incorporated herein by reference in its entirety.

### TECHNICAL FIELD

The present disclosure relates to the technical field of displaying, and particularly relates to a flexible displaying substrate and a fabricating method thereof, and a displaying device.

### BACKGROUND

With the development of the technique of displaying, the technique of flexible displaying is getting increasingly more attention. In order to satisfy the requirements by flexible displaying devices on bending, curling and so on, the displaying devices require to use a flexible substrate, the currently commonly used flexible displaying substrates are formed by a flexible film layer, an inorganic film layer and a buffer layer that are provided in stack.

### SUMMARY

The present disclosure provides a flexible displaying substrate and a fabricating method thereof, and a displaying device.

In an aspect of the present disclosure, the present disclosure provides a flexible displaying substrate. According to an embodiment of the present disclosure, the flexible displaying substrate comprises:

a first flexible film layer;

a first barrier layer, wherein the first barrier layer is provided on a first surface of the first flexible film layer;

a second barrier layer, wherein the second barrier layer is provided on one side of the first barrier layer further away from the first flexible film layer; and

a second flexible film layer, wherein the second flexible film layer is provided between the first barrier layer and the second barrier layer;

wherein at least one of a surface of the first barrier layer further away from the first flexible film layer and a surface of the second barrier layer closer to the first flexible film layer is provided with a slot, and a first orthographic projection of the second flexible film layer on the first flexible film layer and a second orthographic projection of the slot on the first flexible film layer at least partially overlap.

According to an embodiment of the present disclosure, at least part of a contour line of the second orthographic projection is located outside a contour line of the first orthographic projection.

According to an embodiment of the present disclosure, the second flexible film layer fills the slot.

According to an embodiment of the present disclosure, the first barrier layer and the second barrier layer together define an enclosed accommodating space, and the second flexible film layer fills the accommodating space.

According to an embodiment of the present disclosure, the second orthographic projection covers an orthographic projection of a displaying region of the displaying substrate on the first flexible film layer.

According to an embodiment of the present disclosure,

the first barrier layer comprises a first bottom layer and a first border frame;

wherein, the first bottom layer covers the first surface, the first border frame is provided on a surface of the first bottom layer further away from the first flexible film layer, and the first bottom layer and the first border frame together define a first slot.

According to an embodiment of the present disclosure, the first bottom layer and the first border frame are integrally formed.

According to an embodiment of the present disclosure, the second barrier layer comprises a second border frame and a second bottom layer;

the second border frame is provided on the surface of the first barrier layer further away from the first flexible film layer, the second bottom layer is provided on one side of the second border frame further away from the first flexible film layer, and the second border frame and the second bottom layer together define a second slot.

According to an embodiment of the present disclosure, both of the first barrier layer and the second barrier layer are a constant-thickness film layer.

According to an embodiment of the present disclosure, the flexible displaying substrate further comprises a buffer layer, and the buffer layer is provided on the surface of the second barrier layer further away from the first flexible film layer.

In another aspect of the present disclosure, the present disclosure provides a method for fabricating a flexible displaying substrate. According to an embodiment of the present disclosure, the method comprises:

forming a first flexible film layer by spread coating;

depositing a first barrier layer on a first surface of the first flexible film layer;

forming a second flexible film layer by spread coating on a surface of the first barrier layer further away from the first flexible film layer; and

depositing a second barrier layer on sides of the first barrier layer and the second flexible film layer further away from the first flexible film layer;

wherein at least one of the surface of the first barrier layer further away from the first flexible film layer and a surface of the second barrier layer closer to the first flexible film layer is provided with a slot, and a first orthographic projection of the second flexible film layer on the first flexible film layer and a second orthographic projection of the slot on the first flexible film layer at least partially overlap.

According to an embodiment of the present disclosure, the first barrier layer comprises a first bottom layer and a first border frame provided on one surface of the first bottom layer further away from the first flexible film layer, and the step of depositing a first barrier layer on a first surface of the first flexible film layer comprises:

forming sequentially the first bottom layer and the first border frame on the first surface by deposition, and the first bottom layer and the first border frame together define a first slot.

According to an embodiment of the present disclosure, the step of depositing a first barrier layer on a first surface of the first flexible film layer comprises:

forming a first prefabricated layer; and

etching a middle part of the first prefabricated layer, to form the slot in a middle of the first prefabricated layer.

According to an embodiment of the present disclosure, the second barrier layer comprises a second border frame, and a second bottom layer that is provided on a surface of the second border frame further away from the first flexible film layer, and the step of depositing a second barrier layer on sides of the first barrier layer and the second flexible film layer further away from the first flexible film layer:

forming the second border frame by deposition on the surface of the first barrier layer further away from the first flexible film layer; and

forming the second bottom layer by deposition on the surface of the second border frame further away from the first flexible film layer and a surface of the second flexible film layer further away from the first flexible film layer.

In yet another aspect of the present disclosure, the present disclosure provides a displaying device. According to an embodiment of the present disclosure, the displaying device comprises the flexible displaying substrate stated above.

The above description is merely a summary of the technical solutions of the present disclosure. In order to more clearly know the elements of the present disclosure to enable the implementation according to the contents of the description, and in order to make the above and other purposes, features and advantages of the present disclosure more apparent and understandable, the particular embodiments of the present application are provided below.

### BRIEF DESCRIPTION OF THE DRAWINGS

In order to more clearly illustrate the technical solutions of the embodiments of the present disclosure or the related art, the figures that are required to describe the embodiments or the related art will be briefly introduced below. Apparently, the figures that are described below are merely embodiments of the present disclosure, and a person skilled in the art can obtain other figures according to these figures without paying creative work.

FIG. 1 is a planar perspective view of the flexible displaying substrate according to an embodiment of the present disclosure;

FIG. 2 is a schematic sectional structural diagram along the line A-A in FIG. 1;

FIG. 3 is a schematic sectional structural diagram of the flexible displaying substrate according to an embodiment of the present disclosure;

FIG. 4 is a schematic sectional structural diagram of the flexible displaying substrate according to another embodiment of the present disclosure;

FIG. 5 is a schematic sectional structural diagram of the flexible displaying substrate according to another embodiment of the present disclosure;

FIG. 6 is a schematic sectional structural diagram of the flexible displaying substrate according to another embodiment of the present disclosure;

FIG. 7 is a schematic sectional structural diagram of the flexible displaying substrate according to another embodiment of the present disclosure;

FIG. 8 is a schematic sectional structural diagram of the flexible displaying substrate according to another embodiment of the present disclosure;

FIG. 9 is a schematic sectional structural diagram of the flexible displaying substrate according to another embodiment of the present disclosure;

FIG. 10 is a schematic sectional structural diagram of the flexible displaying substrate according to another embodiment of the present disclosure;

FIG. 11 is a schematic sectional structural diagram of the flexible displaying substrate according to another embodiment of the present disclosure;

FIG. 12 is a schematic sectional structural diagram of the flexible displaying substrate according to another embodiment of the present disclosure;

FIG. 13 is a schematic sectional structural diagram of the flexible displaying substrate according to another embodiment of the present disclosure;

FIG. 14 is a schematic flow chart of the method for fabricating a flexible displaying substrate according to an embodiment of the present disclosure;

FIG. 15 is a schematic flow chart of the fabrication of the first barrier layer according to an embodiment of the present disclosure;

FIG. 16 is a schematic flow chart of the fabrication of the first barrier layer according to another embodiment of the present disclosure;

FIG. 17 is a schematic flow chart of the fabrication of the second barrier layer according to an embodiment of the present disclosure;

FIG. 18 is a schematic flow chart of the fabrication of the flexible displaying substrate according to an embodiment of the present disclosure;

FIG. 19 is a schematic flow chart of the fabrication of the flexible displaying substrate according to another embodiment of the present disclosure;

FIG. 20 is a schematic sectional structural diagram of a flexible displaying substrate in the related art; and

FIG. 21 is a schematic diagram of a case of GDS imperfects in the related art.

### DETAILED DESCRIPTION

The embodiments of the present disclosure will be described in detail below. The embodiments described below are exemplary, are merely intended to interpret the present disclosure, and should not be construed as a limitation on the present disclosure. Where an embodiment is not explicitly provided with the particular techniques or conditions, the embodiment is implemented by using the techniques or conditions described in documents in the art or according to a product specification.

The present disclosure is made by the inventor on the basis of the following knowledge and discovery:

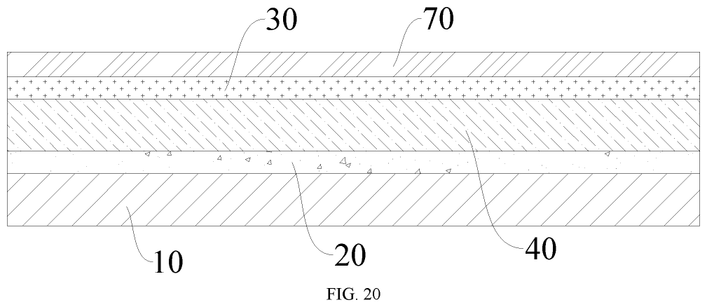

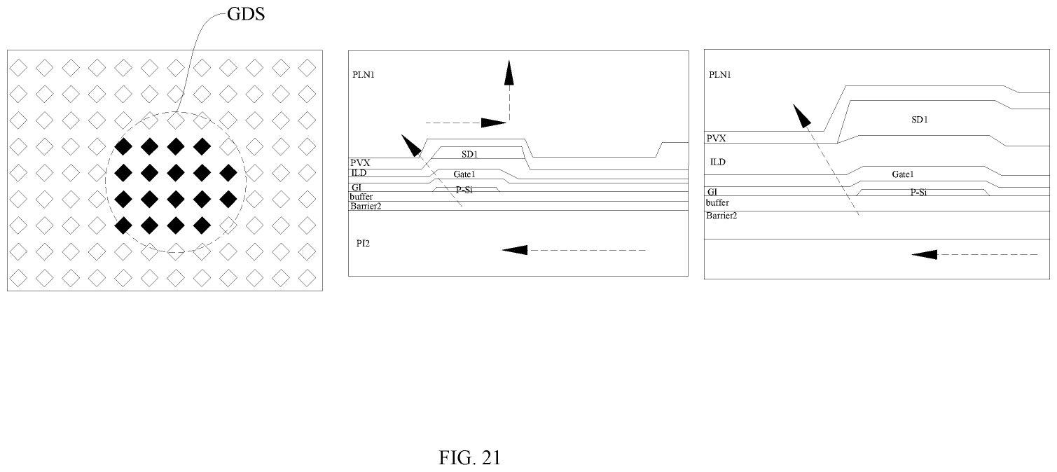

In the related art, the currently commonly used flexible displaying substrates are formed by a flexible film layer, an inorganic film layer and a buffer layer that are provided in stack (the schematic structural diagram may refer to FIG. 20). Because of the characteristics of the materials of the inorganic film layer, micro-cracks are easily generated during the fabrication and the subsequent storage and processing. Moreover, because the second flexible film layer is in communication with the external atmosphere, and because the second flexible film layer is a water absorbing substance, water vapor permeates from the second flexible film layer to the displaying region of the displaying substrate via the micro-cracks, thereby easily resulting in imperfects of large black spots (GDS). FIG. 21 shows a schematic diagram of a particular case of GDS imperfects (the arrow in the figure shows the path of the water-vapor invasion). Aiming at the above problem, the inventor has found out by studying that, by providing the second flexible film layer inside an enclosed accommodating space, to block it from contacting the atmosphere, it can be effectively prevented that water vapor invades into the displaying region via the micro-cracks and the second flexible film layer, which can greatly reduce the risk of GDS imperfects.

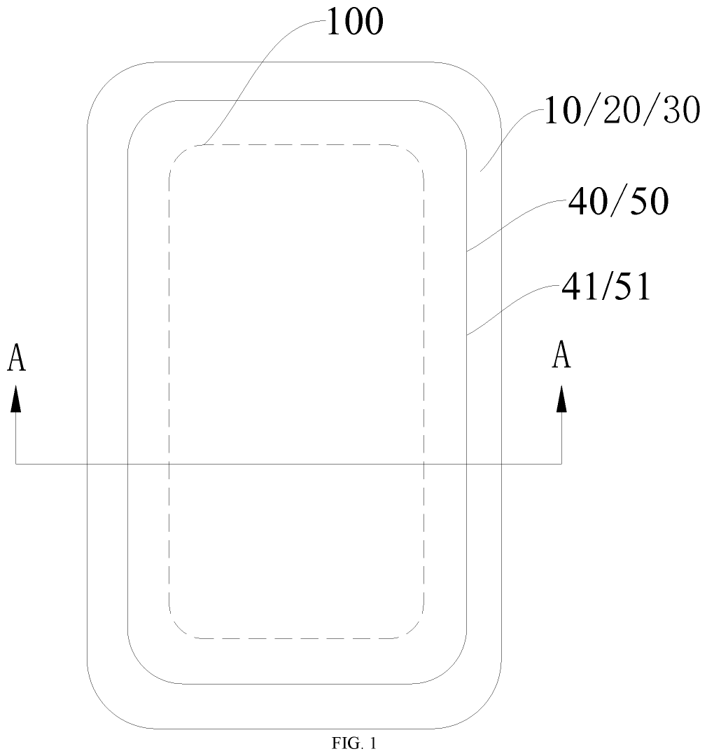

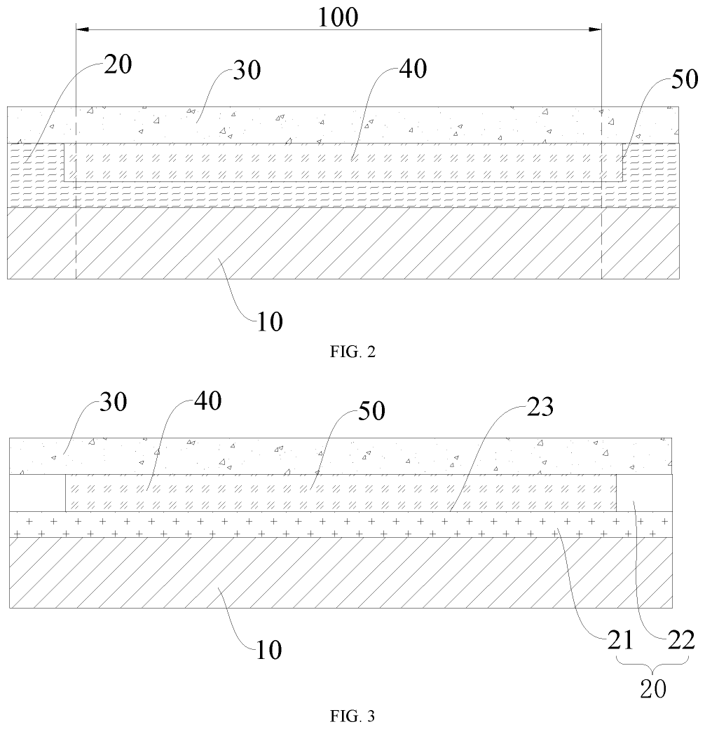

In view of the above, in an aspect of the present disclosure, the present disclosure provides a flexible displaying substrate. According to an embodiment of the present disclosure, referring to FIGS. 1 and 2, the flexible displaying substrate comprises: a first flexible film layer 10; a first barrier layer 20, wherein the first barrier layer 20 is provided on a first surface of the first flexible film layer 10; a second barrier layer 30, wherein the second barrier layer 30 is provided on the side of the first barrier layer 20 that is further away from the first flexible film layer 10; and a second flexible film layer 40, wherein the second flexible film layer 40 is provided between the first barrier layer 20 and the second barrier layer 30; wherein at least one of the surface of the first barrier layer 20 that is further away from the first flexible film layer 10 and the surface of the second barrier layer 30 that is closer to the first flexible film layer 10 is provided with a slot 50, and a first orthographic projection 41 of the second flexible film layer 40 on the first flexible film layer 10 and a second orthographic projection 51 of the slot 50 on the first flexible film layer 10 at least partially overlap (FIGS. 1 and 2 illustrate by taking the case as an example in which the first projection 41 and the second projection 51 exactly completely overlap). The structure of the flexible displaying substrate can effectively prevent the cracks of the inorganic film layer in the middle of the displaying substrate from expanding downwardly, can, by providing the slot, prolong the path of water-vapor invasion into the second flexible film layer, and can even effectively isolate direct contact between the second flexible film layer and the atmosphere, thereby blocking the source of water-vapor invasion, reducing the risk that the external water vapor permeates from the second flexible film layer to the displaying region of the displaying substrate via the micro-cracks, effectively delaying the time when GDS appears, and reducing GDS risk.

According to an embodiment of the present disclosure, the first projection and the second projection may merely partially overlap or exactly completely overlap, or the first projection may fall within the second projection. In some particular embodiments, at least part of the contour line of the second orthographic projection is located on the outer side of the contour line of the first orthographic projection; in other words, part of the side wall of the slot is located on the outer side of the second flexible film layer. Accordingly, the side wall of the slot can effectively prolong the path of water-vapor invasion, or even completely block water-vapor invasion.

According to an embodiment of the present disclosure, in order to better block water-vapor invasion, referring to FIG. 2, the second flexible film layer 40 may fill the slot 50. Accordingly, the whole of the periphery of the second flexible film layer is encircled by the side wall of the slot, which can better block water-vapor invasion. Optionally, in some particular embodiments, referring to FIG. 2, the first barrier layer 20 and the second barrier layer 30 may together define an enclosed accommodating space, and the second flexible film layer 40 fills the accommodating space. Accordingly, the second flexible film layer completely does not contact the atmosphere, which can reach the effect of better blocking water-vapor invasion, and can in turn better delay or prevent GDS imperfects.

According to an embodiment of the present disclosure, in order to prevent affecting the effect of displaying while reducing GDS risk, referring to FIG. 1, the orthographic projection of the accommodating space on the first flexible film layer 10 covers the orthographic projection of the displaying region 100 of the displaying substrate on the first flexible film layer. Particularly, the orthographic projection of the accommodating space on the first flexible film layer 10 may exactly overlap with the orthographic projection of the displaying region 100 of the displaying substrate on the first flexible film layer, and the area of the orthographic projection of the accommodating space on the first flexible film layer 10 may also be greater than the area of the orthographic projection of the displaying region 100 of the displaying substrate on the first flexible film layer (the schematic structural diagrams may refer to FIGS. 1 and 2). Accordingly, the effect of blocking water-vapor invasion is better, and at the same time the effect of displaying is not affected.

According to an embodiment of the present disclosure, as long as the above particular requirements on the blocking of water-vapor invasion are satisfied, the particular structures of the first barrier layer and the second barrier layer are not particularly limited. Particularly, the slot may be formed in merely the first barrier layer, and may also be formed in merely the second barrier layer, and slots may also be formed in both of the first barrier layer and the second barrier layer. Moreover, the first barrier layer and the second barrier layer may be constant-thickness film layers, and may also be nonconstant-thickness film layers. In some particular embodiments, the first barrier layer and the second barrier layer may be independently individually configured to have a bottom layer and a border frame, wherein the bottom layer forms the bottom of the slot, and the border frame forms the side wall of the slot, and may also be constant-thickness film layers, wherein protrusions and depressions of the film layers form the slot.

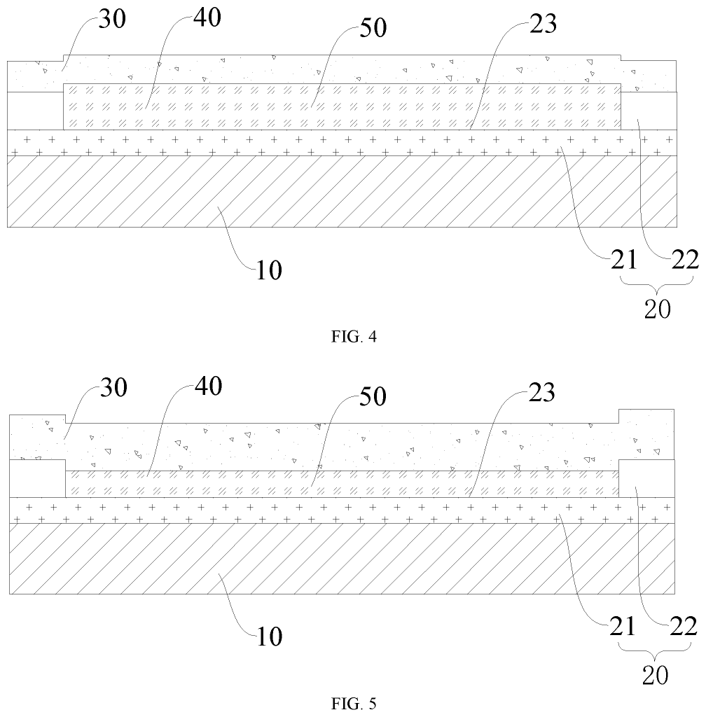

In some particular embodiments, referring to FIGS. 3, 4 and 5, the first barrier layer 20 comprises: a first bottom layer 21, wherein the first bottom layer 21 covers the first surface; and a first border frame 22, wherein the first border frame 22 is provided on the surface of the first bottom layer 21 that is further away from the first flexible film layer 10. Optionally, the first bottom layer 21 and the first border frame 22 may define a first slot 23. The second flexible film layer 40 may exactly fill up the first slot 23 (the schematic structural diagram may refer to FIG. 3), or part of the second flexible film layer 40 may fill up the first slot 23 (the schematic structural diagram may refer to FIG. 4), or the whole of the second flexible film layer 40 may be arranged inside the first slot 23, but cannot fill up the first slot 23 (the schematic structural diagram may refer to FIG. 5).

According to an embodiment of the present disclosure, the particular mode of forming the first bottom layer 21 and the first border frame 22 is not particularly limited. In some particular embodiments, the first bottom layer 21 and the first border frame 22 are integrally formed. In some other particular embodiments, the first bottom layer 21 and the first border frame 22 may also be separately formed.

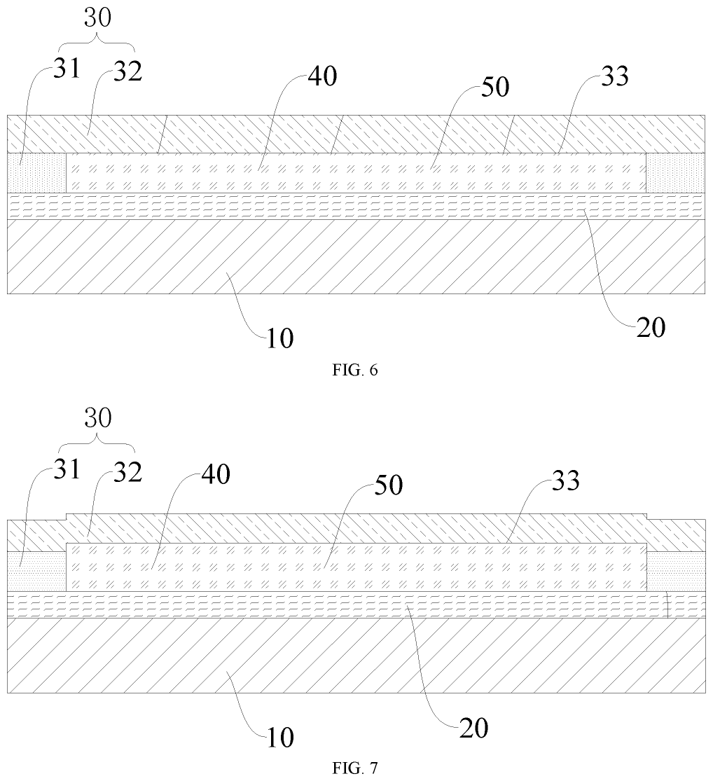

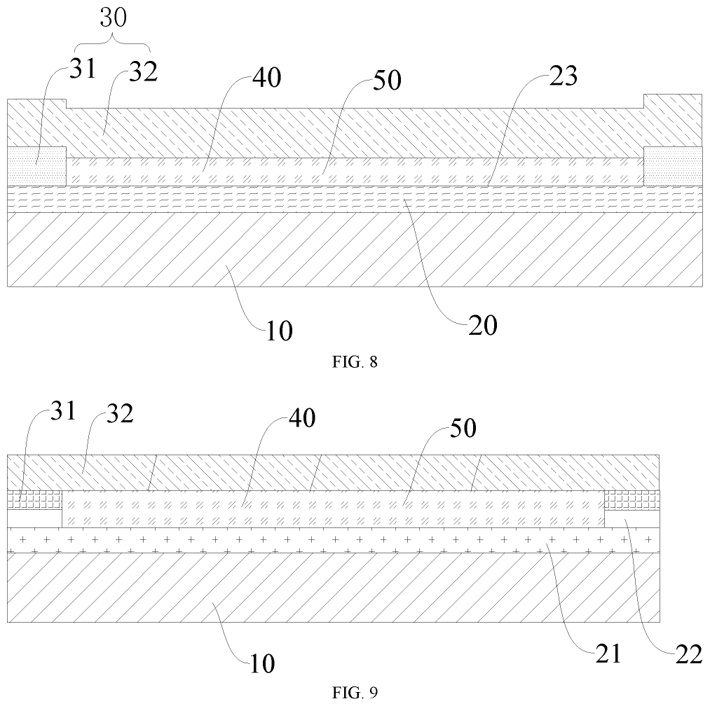

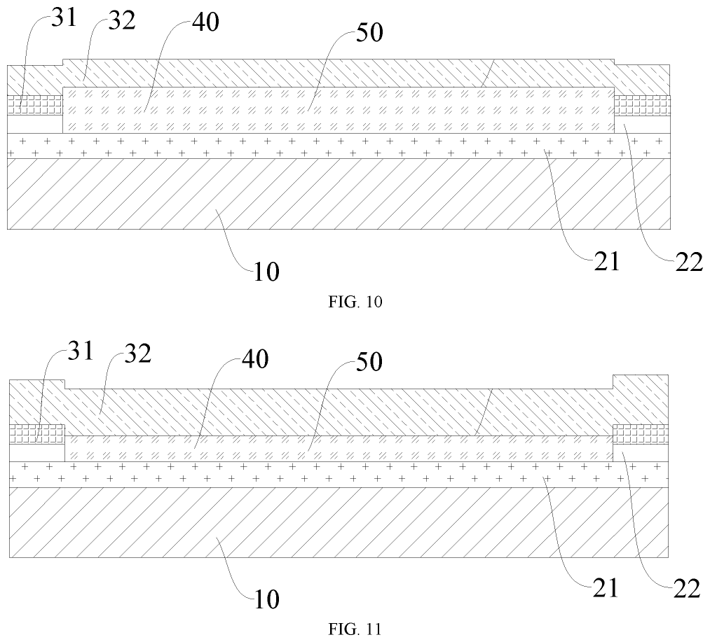

In some particular embodiments, referring to FIGS. 6, 7 and 8, the second barrier layer 30 comprises: a second border frame 31, wherein the second border frame 31 is provided on the surface of the first barrier layer 20 that is further away from the first flexible film layer 10; and a second bottom layer 32, wherein the second bottom layer 32 is provided on the side of the second border frame 31 that is further away from the first flexible film layer 10. Optionally, the second border frame 31 and the second bottom layer 32 may define a second slot 33, and at least part of the second flexible film layer 40 is provided in the second slot 33.

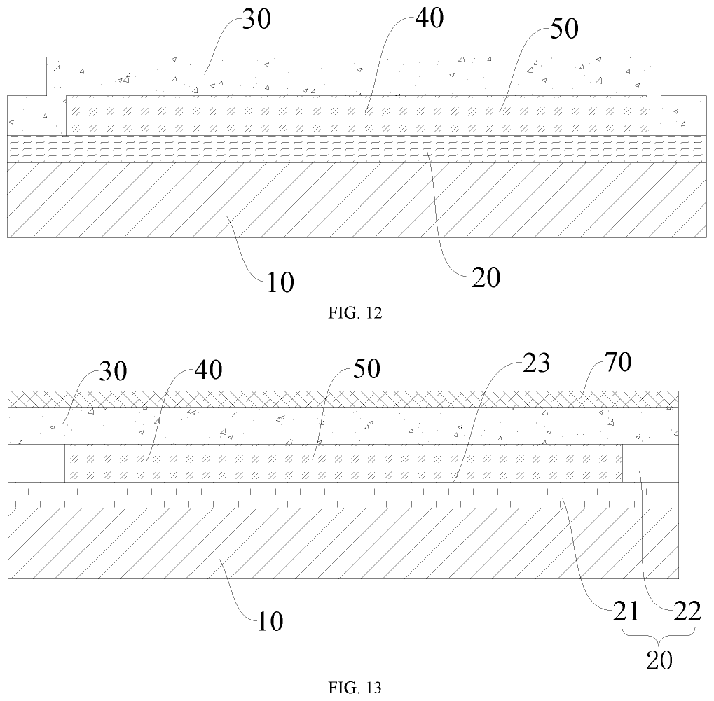

In some other particular embodiments, referring to FIG. 12, both of the first barrier layer 20 and the second barrier layer 30 are a constant-thickness film layer.

According to an embodiment of the present disclosure, referring to FIG. 13, the displaying substrate may further comprise a buffer layer 60, and the buffer layer 60 is provided on the surface of the second barrier layer 30 that is further away from the first flexible film layer. That can prevent the components of the matrix from diffusing to the P-Si zone and thus influencing the electric performance of the displaying substrate, and can further serve to block water to a certain extent.

According to an embodiment of the present disclosure, the materials of the layers of the displaying substrate are not particularly limited, and may be flexibly selected according to practical demands. In some particular embodiments, the first flexible film layer and the second flexible film layer may be formed by using a polymer, and, particularly, may be formed by using polyimide (PI). The first barrier layer and the second barrier layer may be formed by using an inorganic material, and, particularly, may be formed by using SiOₓ, which can prevent external static electricity from influencing the internal circuit. The buffer layer may be formed by using at least one of SiNₓ and SiOₓ, and, particularly, may be a double-layer structure of SiNₓ and SiOₓ. SiNₓ has a good compactness, can prevent the metal ions in the matrix from diffusing to the P-Si zone, and can further serve to block water to a certain extent. Moreover, SiOₓ has a good insulativity and a good thermal insulation, and can reduce the thermal conduction speed, which facilitates to form large crystal grains.

A person skilled in the art can understand that, besides the layer components described above, the displaying substrate may further comprise other necessary components that conventional displaying substrates have, for example, some necessary electric-circuit components, which may particularly be configured by referring to the related art, and is not discussed further herein.

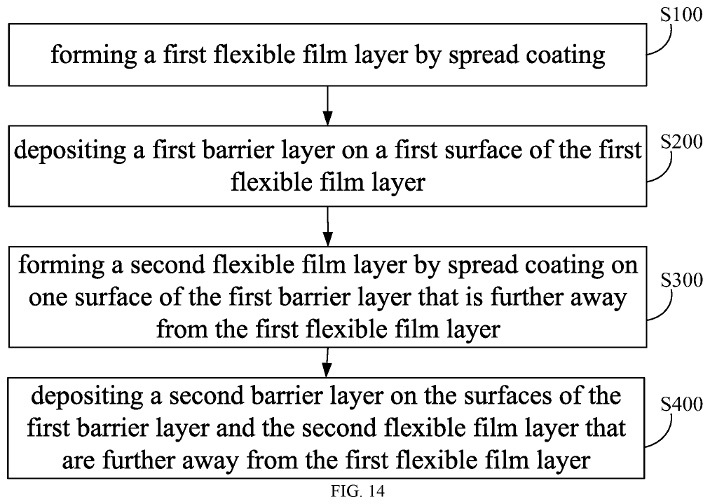

In another aspect of the present disclosure, the present disclosure provides a method for fabricating a flexible displaying substrate. According to an embodiment of the present disclosure, referring to FIG. 14, the method comprises the following steps:

S100: forming a first flexible film layer by spread coating.

Particularly, in this step, the first flexible film layer may be formed by spread coating on a rigid matrix; for example, the first flexible film layer may be formed by spread coating on a glass matrix. Moreover, all of the particular spread-coating steps, parameters and so on may be configured according to practical demands by referring to conventional techniques, and are not discussed further herein. For example, this step may comprise preparing the material for forming the first flexible film layer into a slurry, and subsequently forming the first flexible film layer by spread coating on a glass matrix.

S200: depositing a first barrier layer on a first surface of the first flexible film layer.

Particularly, in this step, the first barrier layer may be formed by chemical vapor deposition. The particularly steps and parameters may be configured according to demands by referring to conventional techniques.

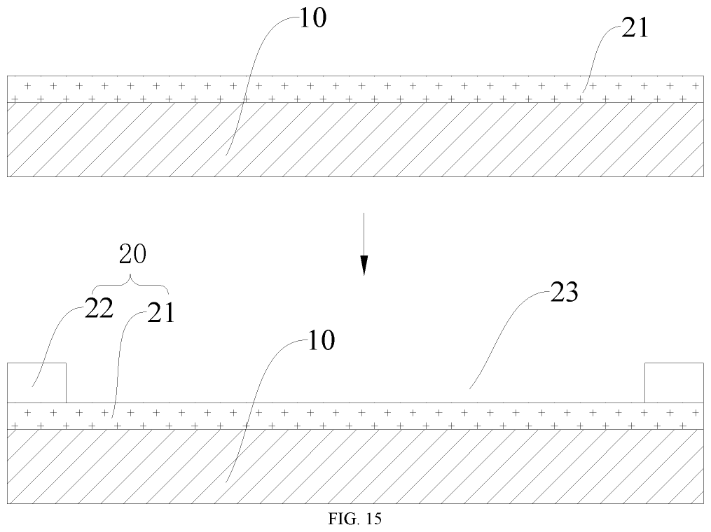

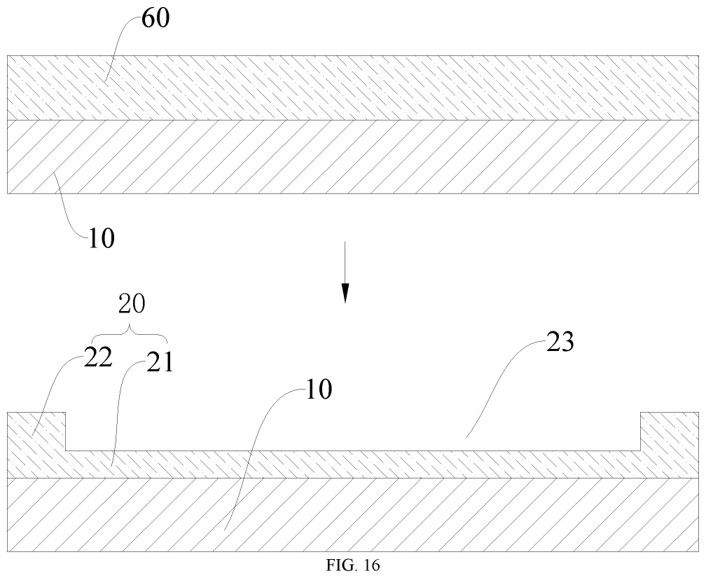

In some particular embodiments, the first barrier layer is a constant-thickness film layer, and in this case the first barrier layer may be formed by one-step deposition (the schematic structural diagram may refer to FIG. 6). In some other particular embodiments, referring to FIG. 3, the first barrier layer 20 comprises a first bottom layer 21 and a first border frame 22, wherein the first border frame 22 is provided on the surface of the first bottom layer 21 that is further away from the first flexible film layer 10, the first bottom layer 21 and the first border frame 22 together define a first slot 23, and at least part of the second flexible film layer 40 is provided in the first slot 23. In this case, the first barrier layer 20 may be formed by two-step deposition. Particularly, referring to FIG. 15, the first bottom layer 21 and the first border frame 22 are formed sequentially on the first surface by deposition. The first barrier layer 20 may also be formed by one-step deposition and one-step etching. Particularly, referring to FIG. 16, the process comprises forming a first prefabricated layer 60, and subsequently etching the middle part of the first prefabricated layer 60, to form the first slot 23 in the middle of the first prefabricated layer 60, wherein the first prefabricated layer that is not removed by etching forms the first bottom layer 21 and the first border frame 22.

S300: forming a second flexible film layer by spread coating on one surface of the first barrier layer that is further away from the first flexible film layer.

Particularly, this step may comprise preparing the material for forming the second flexible film layer into a slurry, and subsequently forming a second flexible film layer by spread coating on one surface of the first barrier layer that is further away from the first flexible film layer. Moreover, all of the particular spread-coating steps, parameters and so on may be configured according to practical demands by referring to conventional techniques, and are not discussed further herein.

S400: depositing a second barrier layer on the surfaces of the first barrier layer and the second flexible film layer that are further away from the first flexible film layer, wherein at least one of the surface of the first barrier layer that is further away from the first flexible film layer and one surface of the second barrier layer that is closer to the first flexible film layer is provided with a slot, and a first orthographic projection of the second flexible film layer on the first flexible film layer and a second orthographic projection of the slot on the first flexible film layer at least partially overlap.

Particularly, in this step, the second barrier layer may be formed by chemical vapor deposition. The particularly steps and parameters may be configured according to demands by referring to conventional techniques.

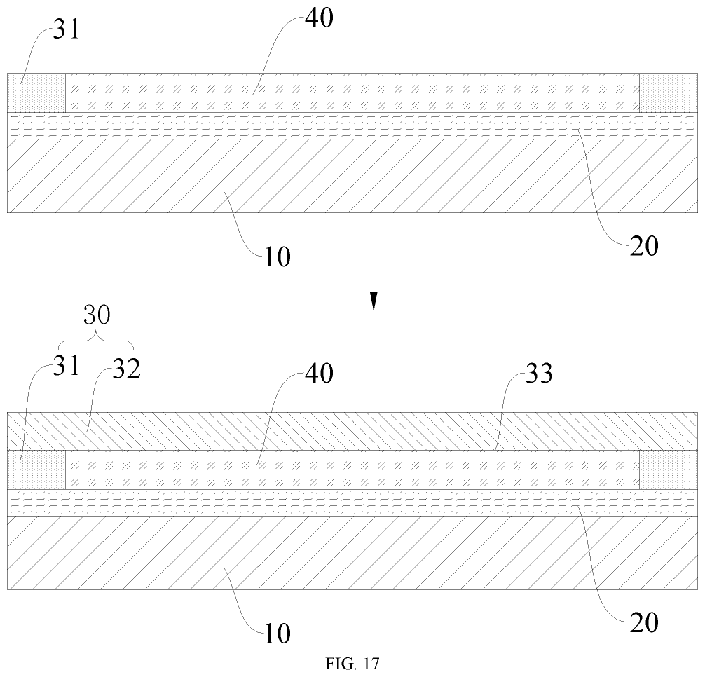

In some particular embodiments, the second barrier layer is a constant-thickness film layer, and in this case the second barrier layer may be formed by one-step deposition (the schematic structural diagram may refer to FIG. 3). In some other particular embodiments, referring to FIG. 6, the second barrier layer 30 comprises a second border frame 31 and a second bottom layer 32, wherein the second border frame 31 is provided on the surface of the first barrier layer 20 that is further away from the first flexible film layer 10, the second bottom layer 32 is provided on the side of the second border frame 31 that is further away from the first flexible film layer 10, the second bottom layer 32 and the second border frame 31 together define a second slot 33, and at least part of the second flexible film layer 40 is provided in the second slot 33. In this case, referring to FIG. 17, the second barrier layer 30 may be formed by using the following steps: forming the second border frame 31 by deposition on the surface of the first barrier layer 20 that is further away from the first flexible film layer 10; forming the second bottom layer 32 by deposition on the surface of the second border frame 31 that is further away from the first flexible film layer 10 and the surface of the second flexible film layer 40 that is further away from the first flexible film layer 10.

The method has simple and convenient steps, has a high compatibility with the related art, and does not need too many extra steps. Furthermore, the obtained flexible displaying substrate can effectively prevent the cracks of the inorganic film layer in the middle of the displaying substrate from expanding downwardly, and, by providing the second flexible film layer inside the enclosed accommodating space, can effectively isolate direct contact between the second flexible film layer and the atmosphere, thereby blocking the source of water-vapor invasion, effectively delaying the time when GDS appears, and reducing GDS risk.

The method for fabricating a flexible displaying substrate according to the present disclosure will be described in detail below by taking the case as an example in which the first barrier layer comprises the first bottom layer and the first border frame and the second barrier layer is a constant-thickness film layer.

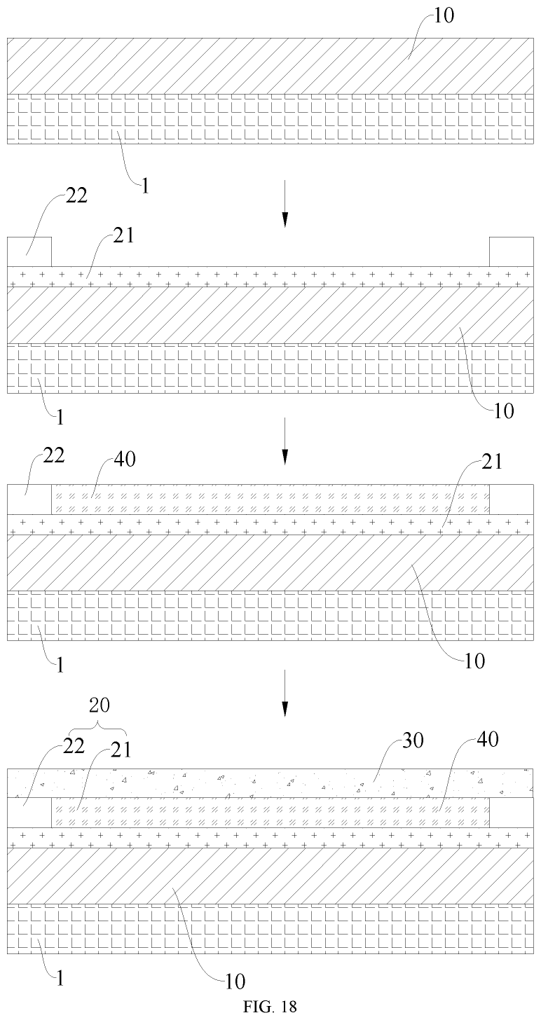

In a particular embodiment, referring to FIG. 18, the displaying substrate is fabricated by using the following steps:

1) forming the first flexible film layer 10 by spread coating on a glass substrate 1;

2) forming the first bottom layer 21 and the first border frame 22 sequentially on the first surface of the first flexible film layer 10 that is further away from the glass substrate by deposition;

3) forming the second flexible film layer 40 by spread coating on the surface of the first barrier layer 20 that is further away from the first flexible film layer 10; and

4) depositing the second barrier layer 30 on the surfaces of the first barrier layer 20 and the second flexible film layer 40 that are further away from the first flexible film layer 10.

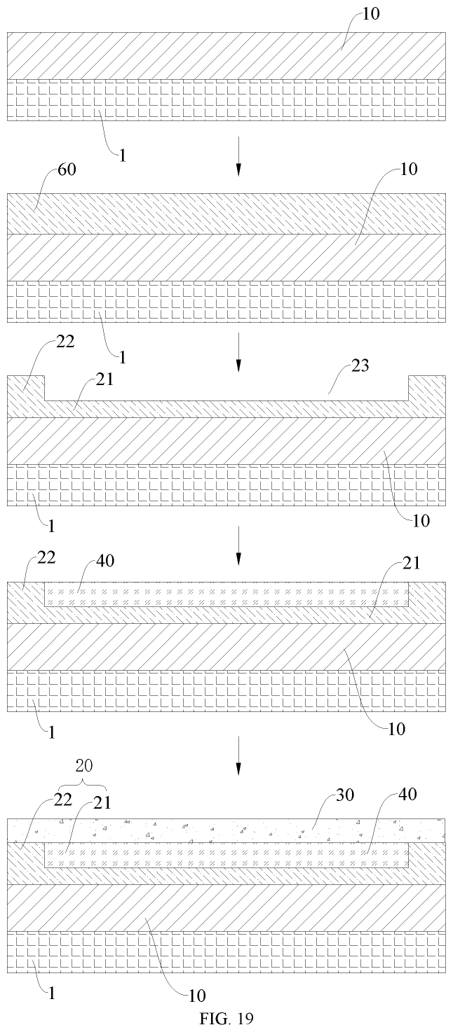

In another particular embodiment, referring to FIG. 19, the displaying substrate is fabricated by using the following steps:

1) forming the first flexible film layer 10 by spread coating on a glass substrate 1;

2) forming the first prefabricated layer 60;

3) etching the middle part of the first prefabricated layer 60, to form the first slot 23 in the middle of the first prefabricated layer 60, wherein the first prefabricated layer that is not removed by etching forms the first bottom layer 21 and the first border frame 22;

4) forming the second flexible film layer 40 by spread coating on the surface of the first barrier layer 20 that is further away from the first flexible film layer 10; and

5) depositing the second barrier layer 30 on the surfaces of the first barrier layer 20 and the second flexible film layer 40 that are further away from the first flexible film layer 10.

It can be understood that, besides the steps described above, the method for fabricating a flexible displaying substrate may further comprise necessary steps for fabricating conventional displaying substrates, such as the steps for forming necessary electric-circuit components, which are not discussed further herein.

In yet another aspect of the present disclosure, the present disclosure provides a displaying device. According to an embodiment of the present disclosure, the displaying device comprises the flexible displaying substrate stated above. The displaying device has all of the characteristics and the advantages of the flexible displaying substrate stated above, which are not discussed further herein.

According to an embodiment of the present disclosure, the type of the displaying device is not particularly limited, and it may be a display panel, a mobile phone, a television set, a game machine, a tablet personal computer, a wearable device and so on. Moreover, a person skilled in the art can understand that, besides the displaying substrate stated above, the displaying device may further comprise structures or components necessary for conventional displaying devices. Taking a mobile phone as an example, it may further comprise a light emitting device, a touch-controlling screen, a battery, a housing, a photographing module, a fingerprint identification module and so on, which are not described in detail herein.

In the description of the present disclosure, it should be understood that the terms “first” and “second” are merely for the purpose of describing, and should not be construed as indicating or implying the degrees of importance or implicitly indicating the quantity of the specified technical features. Accordingly, the features defined by “first” or “second” may explicitly or implicitly comprise one or more of the features. In the description of the present disclosure, the meaning of “plurality of” is “two or more”, unless explicitly and particularly defined otherwise.

In the description of the present disclosure, the description referring to the terms “an embodiment”, “some embodiments”, “example”, “particular example” or “some examples” and so on means that particular features, structures, materials or characteristics described with reference to the embodiment or example are comprised in at least one of the embodiments or examples of the present disclosure. In the description, the illustrative expressions of the above terms do not necessarily relate to the same embodiment or example. Furthermore, the described particular features, structures, materials or characteristics may be combined in one or more embodiments or examples in a suitable form. Furthermore, subject to avoiding contradiction, a person skilled in the art may combine different embodiments or examples described in the description and the features of the different embodiments or examples.

Although the embodiments of the present disclosure have already been illustrated and described above, it can be understood that the above embodiments are illustrative, and should not be construed as a limitation on the present disclosure, and a person skilled in the art may make variations, modifications, substitutions and improvements to the above embodiments within the scope of the present disclosure.

1. A flexible displaying substrate, wherein the flexible displaying substrate comprises:
a first flexible film layer;
a first barrier layer, wherein the first barrier layer is provided on a first surface of the first flexible film layer;
a second barrier layer, wherein the second barrier layer is provided on one side of the first barrier layer further away from the first flexible film layer; and
a second flexible film layer, wherein the second flexible film layer is provided between the first barrier layer and the second barrier layer;
wherein at least one of a surface of the first barrier layer further away from the first flexible film layer and a surface of the second barrier layer closer to the first flexible film layer is provided with a slot, and a first orthographic projection of the second flexible film layer on the first flexible film layer and a second orthographic projection of the slot on the first flexible film layer at least partially overlap.

2. The flexible displaying substrate according to claim 1, wherein at least part of a contour line of the second orthographic projection is located outside a contour line of the first orthographic projection.

3. The flexible displaying substrate according to claim 2, wherein the second flexible film layer fills the slot.

4. The flexible displaying substrate according to claim 3, wherein the first barrier layer and the second barrier layer together define an enclosed accommodating space, and the second flexible film layer fills the accommodating space.

5. The flexible displaying substrate according to claim 1, wherein the second orthographic projection covers an orthographic projection of a displaying region of the displaying substrate on the first flexible film layer.

6. The flexible displaying substrate according to claim 1, wherein
the first barrier layer comprises a first bottom layer and a first border frame;
wherein, the first bottom layer covers the first surface, the first border frame is provided on a surface of the first bottom layer further away from the first flexible film layer, and the first bottom layer and the first border frame together define a first slot.

7. The flexible displaying substrate according to claim 6, wherein the first bottom layer and the first border frame are integrally formed.

8. The flexible displaying substrate according to claim 1, wherein the second barrier layer comprises a second border frame and a second bottom layer;
the second border frame is provided on the surface of the first barrier layer further away from the first flexible film layer, the second bottom layer is provided on one side of the second border frame further away from the first flexible film layer, and the second border frame and the second bottom layer together define a second slot.

9. The flexible displaying substrate according to claim 1, wherein both of the first barrier layer and the second barrier layer are a constant-thickness film layer.

10. The flexible displaying substrate according to claim 1, wherein the flexible displaying substrate further comprises a buffer layer, and the buffer layer is provided on the surface of the second barrier layer further away from the first flexible film layer.

11. A method for fabricating a flexible displaying substrate, wherein the method comprises:
forming a first flexible film layer by spread coating;
depositing a first barrier layer on a first surface of the first flexible film layer;
forming a second flexible film layer by spread coating on a surface of the first barrier layer further away from the first flexible film layer; and
depositing a second barrier layer on sides of the first barrier layer and the second flexible film layer further away from the first flexible film layer;
wherein at least one of the surface of the first barrier layer further away from the first flexible film layer and a surface of the second barrier layer closer to the first flexible film layer is provided with a slot, and a first orthographic projection of the second flexible film layer on the first flexible film layer and a second orthographic projection of the slot on the first flexible film layer at least partially overlap.

12. The method according to claim 11, wherein the first barrier layer comprises a first bottom layer and a first border frame provided on one surface of the first bottom layer further away from the first flexible film layer, and the step of depositing a first barrier layer on a first surface of the first flexible film layer comprises:
forming sequentially the first bottom layer and the first border frame on the first surface by deposition, and the first bottom layer and the first border frame together define a first slot.

13. The method according to claim 11, wherein the step of depositing a first barrier layer on a first surface of the first flexible film layer comprises:
forming a first prefabricated layer; and
etching a middle part of the first prefabricated layer, to form the slot in a middle of the first prefabricated layer.

14. The method according to claim 11, wherein the second barrier layer comprises a second border frame, and a second bottom layer that is provided on a surface of the second border frame further away from the first flexible film layer, and the step of depositing a second barrier layer on sides of the first barrier layer and the second flexible film layer further away from the first flexible film layer:
forming the second border frame by deposition on the surface of the first barrier layer further away from the first flexible film layer; and
forming the second bottom layer by deposition on the surface of the second border frame further away from the first flexible film layer and a surface of the second flexible film layer further away from the first flexible film layer.

15. A displaying device, wherein the displaying device comprises the flexible displaying substrate according to claim 1.
